(19) United States
(12) Patent Application Publication
(10) Pub. No.: US 2013/0016480 A1
(43) Pub. Date: Jan. 17, 2013

(54) PRINTED CIRCUIT BOARD HAVING HEAT GATHERING STRUCTURES AND MANUFACTURING PROCESS THEREOF

(71) Applicant: Wen-Ji SUN, Shanghai (CN)

(72) Inventor: Wen-Ji SUN, Shanghai (CN)

(73) Assignee: Delta Electronics (Shanghai) Co., Ltd

(21) Appl. No.: 13/293,115

(22) Filed: Nov. 9, 2011

(30) Foreign Application Priority Data
Jul. 15, 2011 (CN) 201110199467.X

(51) Int. Cl. H05K 7/20; H05K 3/00

(52) U.S. Cl. 361/720; 29/829

(57) ABSTRACT

A printed circuit board (PCB) having heat gathering structures is used for enabling electronic components with pins to be inserted thereon. The PCB includes a base, at least one insertion hole, and at least one heat gathering hole. The base has a first surface and a second surface. The insertion hole penetrates the base, and the base has soldering pad on the periphery of the insertion hole. A first electric conducting layer is disposed on the inner wall of each insertion hole. The heat gathering hole penetrates the base. A second electric conducting layer is disposed on the inner wall of each heat gathering hole. The temperature of the insert holes will be increased for improving soldering process. A manufacturing process of the PCB having heat gathering structures is also disclosed.

### BACKGROUND

1. Technical Field

The present invention generally relates to a printed circuit board to be inserted with an electronic component, and more specifically, to a printed circuit board having heat gathering structures and a manufacturing process of the printed circuit board.

2. Related Art

Generally speaking, a conventional printed circuit board (PCB) has not only built-in circuits but also electronic components inserted thereon. Many of the electronic components have pins. The PCB must have insertion holes corresponding to the pins of the electronic components so that the electronic components with pins can be placed onto the PCB. Specifically, the insertion holes allow the pins to be inserted therein and soldered to the back surface of the PCB.

Nowadays, PCBs are fast manufactured through mass production. A solder furnace is used to apply solder to the ends of the pins of the electronic components and solder the pins to the back surface of the PCB. However, because the electronic components only stay in the solder furnace for a short time and the conducting heat on the insertion holes of the PCB is slow, the time is frequently not enough for the solder in the solder furnace to move upward onto the pins of the electronic components. This may cause insufficient solder to be adhered to the pins, thereby affecting the PCB's electronic characteristics, and reducing the PCB yield rate.

To resolve this problem of insufficient adherence of solder, some manufacturers use additional manual process to add solder. However, this additional manual process will spend additional labor force and time. Furthermore, it's still uncertain whether the electronic components can maintain their electronic characteristics after the manual soldering process. As a result, the manufacturing efficiency of PCBs is still greatly affected by the problem of insufficient soldering.

### BRIEF SUMMARY

To resolve the problem of insufficient solder adherence to a pin, and increase the PCB yield rate, the present invention provides a printed circuit board (PCB) with an insertion hole having heat gathering structures and the PCB's manufacturing process.

To avoid additional manual soldering so as to enhance the PCB production efficiency, the present invention provides a PCB with an insertion hole having heat gathering structures and the PCB's manufacturing process.

In an embodiment, the present invention provides a PCB having at least one insertion hole with heat gathering structures for enabling at least one electronic component having a pin to be inserted thereon. The PCB includes a base, the insertion hole, and at least one heat gathering hole. The base is a two-layer board or a multi-layer board. It has a first surface and a second surface opposite to the first surface. The insertion hole allows the pin of the electronic component to be inserted therein. The insertion hole penetrates the base. The first surface has a first soldering pad on the periphery of the insertion hole, and the second surface has a second soldering pad on the periphery of the insertion hole. The inner wall of the insertion hole has a first electric conducting layer electrically connected to the first soldering pad and the second soldering pad. The heat gathering hole penetrates the base and is disposed around the insertion hole. The inner wall of the heat gathering hole has a second electric conducting layer electrically connected to the first soldering pad and the second soldering pad.

In another embodiment, the present invention provides a PCB having at least one insertion hole with heat gathering structures for at least one electronic component having a pin to be inserted thereon. The PCB includes a base, the insertion hole, and at least one heat gathering hole. The base is a two-layer board or a multi-layer board. The insertion hole allows the pin of the electronic component to be inserted therein. The insertion hole penetrates the base. The heat gathering hole penetrates the base and is disposed around the insertion hole.

In addition, the present invention also provides a process for manufacturing a printed circuit board for enabling at least one electronic component having a pin to be inserted thereon. The process includes the steps of providing a base; disposing at least one insertion hole on the base; and disposing at least one heat gathering hole around the insertion hole.

In the present invention, the base has an insertion hole and there is a soldering pad on the periphery of the insertion hole. There is a heat gathering hole located adjacent to the soldering pad to serve as the heat gathering structures of the insertion hole. Accordingly, when the PCB is sent into a solder furnace, solder will adhere to the insertion hole and the heat gathering hole. Being adhered by solder or heated up by the hot air in the solder furnace, the heat gathering hole will help to increase the temperature of the insertion hole so as to enable sufficient solder to adhere to the insertion hole. As a result, the PCB yield rate is increased. Furthermore, the disposition of the heat gathering hole avoids additional soldering process and will not increase the cost or working hours. Therefore, the present invention can increase the manufacturing efficiency of PCBs.

It is to be understood that both the foregoing general description and the following detailed description are exemplary and explanatory only and are not restrictive of the invention, as claimed.

### BRIEF DESCRIPTION OF THE DRAWINGS

FIG. 1 is a schematic diagram showing how the electronic component is to be inserted onto the PCB of the present invention;

FIG. 2 is a schematic diagram showing the electronic component combined with the PCB of the present invention;

FIG. 3 is a sectional view showing the electronic component combined with the PCB of the present invention;

FIG. 4 is a perspective view showing the appearance of the PCB of the present invention;

FIG. 5 is a sectional view of the PCB of the present invention;

FIG. 6 is a planar view of the PCB according to another embodiment of the present invention;

FIG. 7 is a planar view of the PCB according to further another embodiment of the present invention;

FIG. 8 is a sectional view of FIG. 7; and

FIG. 9 is a flow chart of the manufacturing process of the PCB of the present invention.

### DETAILED DESCRIPTION

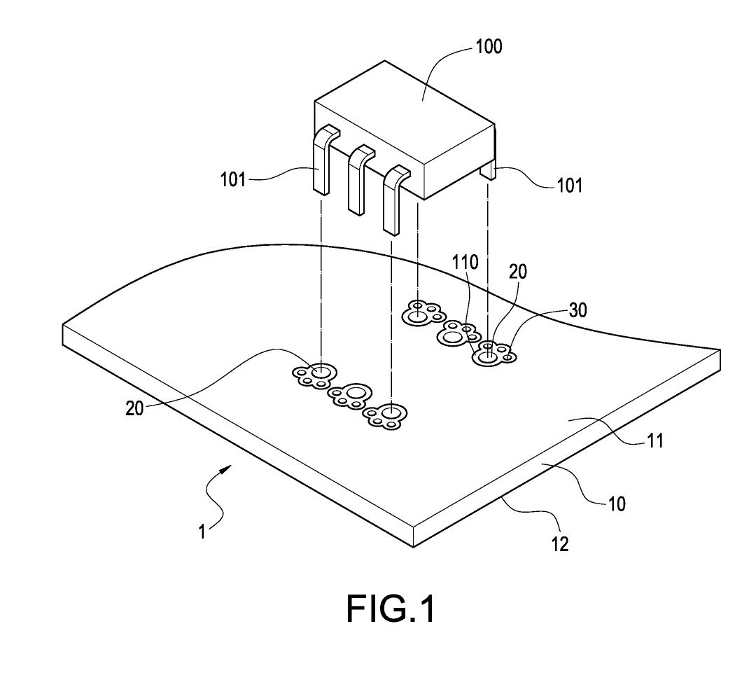

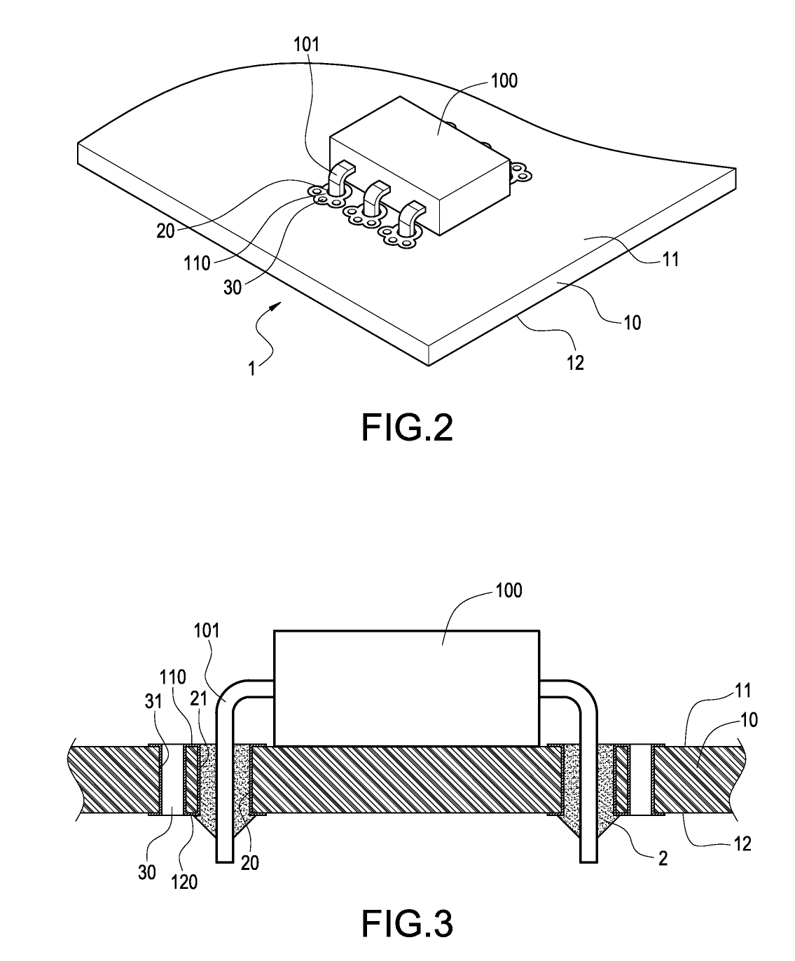

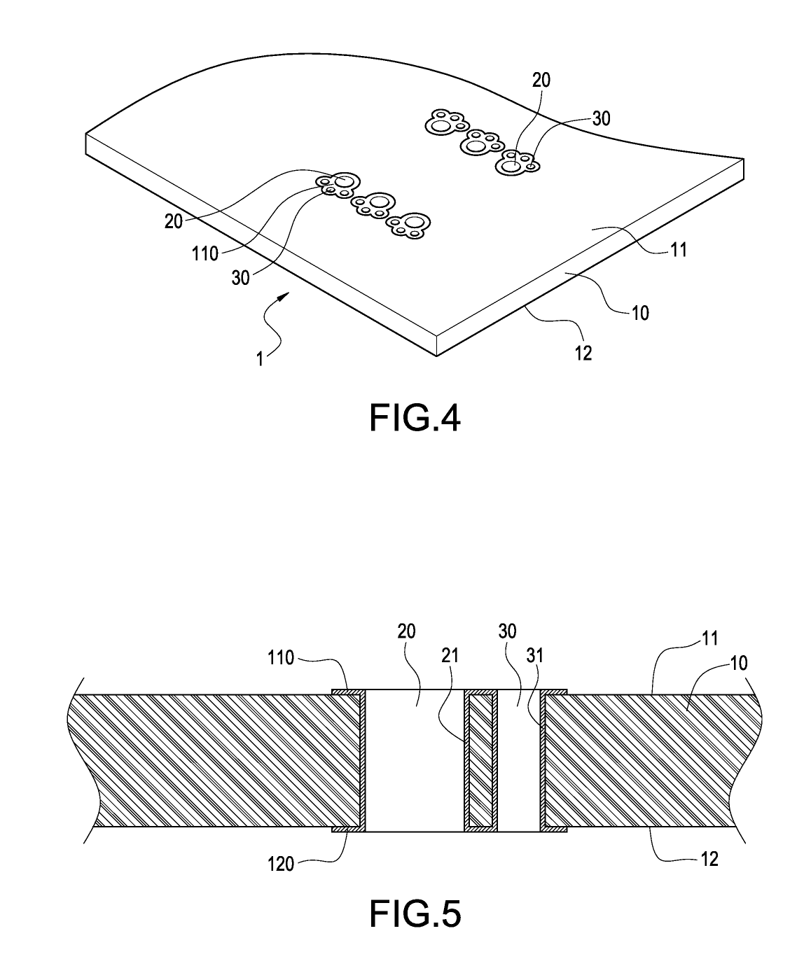

Please refer to FIG. 1 to FIG. 5. These figures illustrate a first embodiment of the present invention. The PCB 1 having insertion holes that have heat gathering structures in this embodiment allows at least one electronic component 100 having a pin 101 to be inserted thereon. The PCB 1 has a base 10, at least one insertion hole 20, and at least one heat gathering hole 30.

The base 10 is a two-layer board or a multi-layer board. The base 10 has a first surface 11 and a second surface 12 opposite to the first surface 11.

The insertion hole 20 is disposed on the base 10 and allows the pin 101 of the electronic component 100 to be inserted therein. The insertion hole 20 penetrates the base 10. The first surface 11 has a first soldering pad 110 on the periphery of the insertion hole 20. The second surface 12 has a second soldering pad 120 on the periphery of the insertion hole 20 as shown in FIG. 3. The first soldering pad 110 and the second soldering pad 120 are around the insertion hole 20. The one-side width of the first soldering pad 110 and the second soldering pad 120 are, but are not limited to, 0.2 mm. Furthermore, the inner wall of the insertion hole 20 has a first electric conducting layer 21 electrically connected to the first soldering pad 110 and the second soldering pad 120.

The heat gathering hole 30 is a through-hole penetrating the base 10. The heat gathering hole 30 is located adjacent to both the first soldering pad 110 and the second soldering pad 120. The inner wall of the heat gathering hole 30 has a second electric conducting layer 31. The second electric conducting layer 31 is electrically connected to first soldering pad 110 and the second soldering pad 120. In this embodiment, the first electric conducting layer 21 and the second electric conducting layer 31 are copper foil layers. The insertion hole 20 and the heat gathering hole 30 are circular or elliptic holes. However, these characteristics do not limit the present invention.

The pin 101 is inserted into the insertion hole 20 from the first surface 11 towards the second surface 12 so that the electronic component 100 is disposed on the first surface 11 of the base 10. Then, the PCB 1 is sent into a solder furnace, which is not shown in the figures, having solder 2. By doing so, the solder 2 will adhere to the insertion hole 20 and the heat gathering hole 30. The heat in the solder furnace will cause the solder 2 to solder the end of the pin 101 onto the second surface 12 of the base 10. The result is that the electronic component 100 will be electrically connected to the PCB 1.

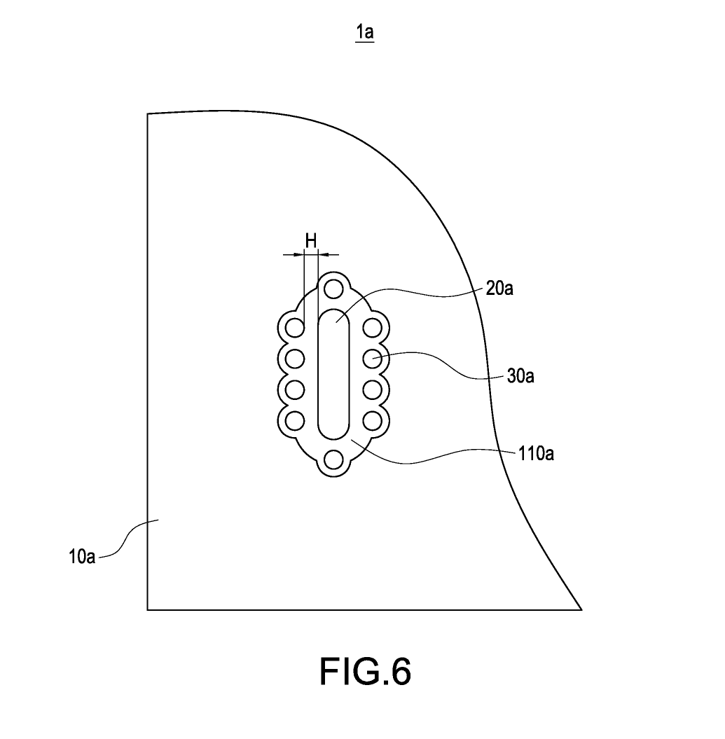

Please refer to FIG. 6, which is the planar view of a second embodiment of the present invention's PCB with an insertion hole having heat gathering structures. The PCB 1a includes a base 10a, at least one insertion hole 20a, and a plurality of heat gathering holes 30a. The first surface of the base 10a has a first soldering pad 110a on the periphery of the insertion hole 20a. The insertion hole 20a is an oblong hole. The heat gathering holes 30a are circular holes. There is a distance H between the heat gathering holes 30a and the insertion hole 20a. For example, the distance H is ranged from 0.4.mm to 0.6 mm, the aperture sizes of the heat gathering holes 30a are ranged from 0.6 mm to 0.8 mm, and the aperture size of the insertion hole 20a is ranged from 1.0 mm to 4.1 mm.

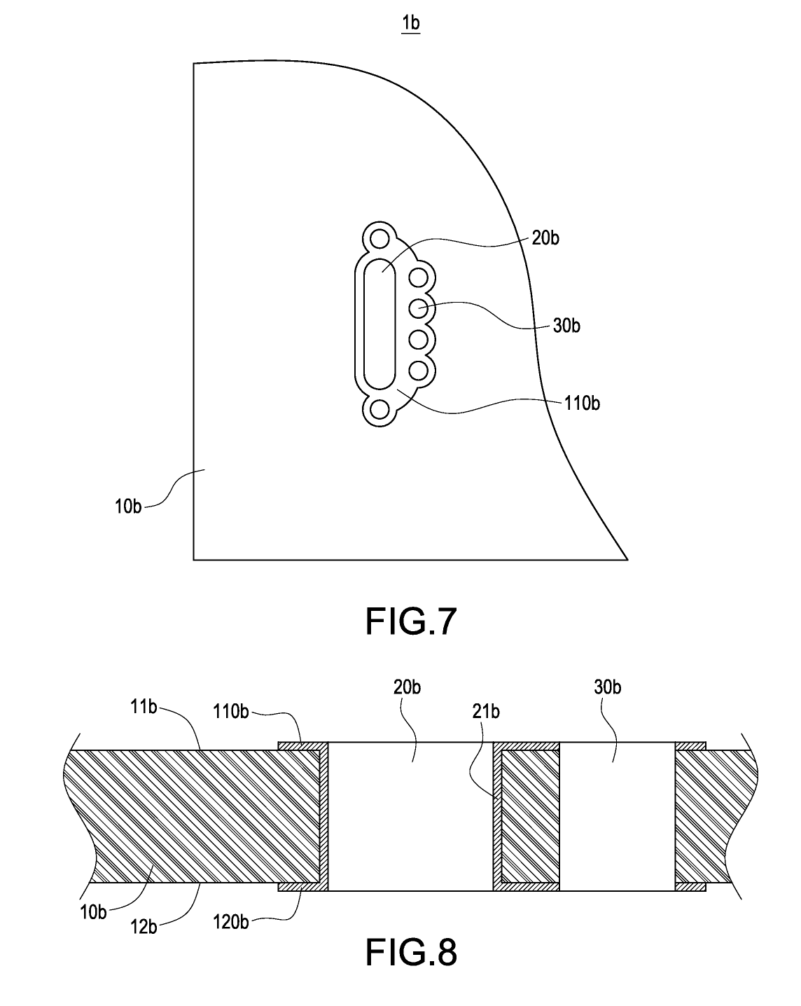

Please refer to FIG. 7 and FIG. 8 showing the third embodiment of the present invention. The PCB 1b has a base 10b, at least one insertion hole 20b, and a plurality of heat gathering holes 30b. The first surface 11b of the base 10b has a first soldering pad 110b on the periphery of the insertion hole 20b. Furthermore, the second surface 12b of the base 10b has a second soldering pad 120b on the periphery of the insertion hole 20b. Because the first soldering pad 110b and the second soldering pad 120b around the insertion hole 20b must allow solder to adhere thereon, these two pads 110b and 120b are bare copper or copper foil. The number of the heat gathering holes 30b is proportional to the square measure of the copper foil on the periphery of the insertion hole 20b.

Furthermore, the number of the heat gathering holes 30b can also be proportional to the aperture size of the insertion hole 20a. For example, the ratio of the aperture size of the insertion hole 20a to the number of the heat gathering holes 30b is ranged from 15% to 35%. Furthermore, this embodiment is different from the first embodiment in that the inner wall of the heat gathering hole 30b does not have an electric conducting layer. When the PCB 1b is sent into the solder furnace, the solder will adhere to the insertion hole 20b. The heat gathering holes 30b will be heat up by the hot air in the solder furnace but will not be adhered by the solder. The disposition of the heat gathering holes 30b can help the temperature of the insertion hole 20b to increase.

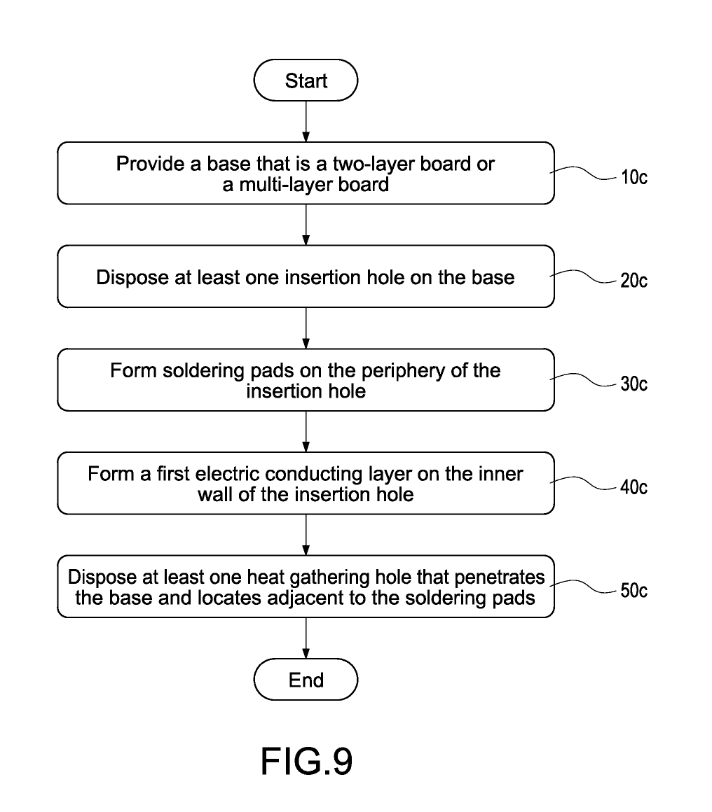

Please refer to FIG. 9 illustrating the manufacturing process of the present invention's PCB with heat gathering structures. Please also refer to FIG. 1 to FIG. 5. At Step 10c, a base 10, which is either a two-layer board or a multi-layer board, is provided. The base 10 has a first surface 11 and a second surface 12 opposite to the first surface 11. Then, at Step 20c, at least one insertion hole 20 is disposed on the base 10, where the insertion hole 20 penetrates the base 10. Next, at step 30c, a first soldering pad 110 and a second soldering pad 120 are formed on the periphery of the insertion hole 20 on the first surface 11 and the second surface 12 of the base 10, respectively. At step 40c, a first electric conducting layer 21 is formed on the inner wall of the insertion hole 20, where the first electric conducting layer 21 is electrically connected to the first soldering pad 110 and the second soldering pad 120. Finally, at step 50c, at least one heat gathering hole 30 is formed on the location of the first soldering pad 110 and the second soldering pad 120, where the heat gathering hole 30 penetrates the base 10.

The manufacturing process can further include another step, at which a second electric conducting layer 31 is formed on the inner wall of the heat gathering hole 30. The second electric conducting layer 31 is electrically connected to the first soldering pad 110 and the second soldering pad 120. After the PCB 1 has been manufactured, the pin 101 of the electronic component 100 is inserted into the insertion hole 20 from the first surface 11 to the second surface 12. Then, the PCB 1 inserted with the electronic component 100 is sent into a solder furnace having solder 2. The solder 2 will adhere to the inner wall of the insertion hole 20. The solder 2 will solder the pin 101 of the electronic component 100 onto the second surface 12, thereby causing the electronic component 100 to be electrically connected to the PCB 1.

Based upon above, the present invention uses the heat gathering hole(s) surrounding the insertion hole to enhance the soldering process. The insertion hole requires no additional manual soldering after the PCB is sent into the solder furnace. As a result, the present invention avoids the time and labor force used in the additional manual soldering process, and increases the quality and yield rate of the products.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A printed circuit board (PCB) having heat gathering structures for enabling at least one electronic component having a pin to be inserted thereon, the PCB comprising:
a base having a first surface and a second surface opposite to the first surface;
at least one insertion hole for allowing the pin of the electronic component to be inserted therein, wherein the insertion hole penetrates the base, the first surface has a first soldering pad on the periphery of the insertion hole, the second surface has a second soldering pad on the periphery of the insertion hole, and an inner wall of the insertion hole has a first electric conducting layer electrically connected to the first soldering pad and the second soldering pad; and
at least one heat gathering hole penetrating the base and disposed around the insertion hole, wherein an inner wall of the heat gathering hole has a second electric conducting layer electrically connected to the first soldering pad and the second soldering pad.

2. The PCB of claim 1, wherein the first soldering pad and the second soldering pad are disposed around the insertion hole or on the periphery of the insertion hole, respectively.

3. The PCB of claim 1, wherein the first soldering pad and the second soldering pad are bare copper or copper foil, a number of the at least one heat gathering hole is proportional to an area of the copper foil on a periphery of the insertion hole.

4. The PCB of claim 1, wherein one-side widths of the first soldering pad and the second soldering pad are 0.2 mm, respectively.

5. The PCB of claim 1, wherein the first electric conducting layer and the second electric conducting layer are copper foil layers, respectively.

6. A printed circuit board (PCB) for enabling at least one electronic component having a pin to be inserted thereon, the PCB comprising:
a base;
at least one insertion hole for allowing the pin of the electronic component to be inserted therein, wherein the insertion hole penetrates the base; and
at least one heat gathering hole penetrating the base and being disposed around the insertion hole.

7. The PCB of claim 6, wherein the base has a first surface and a second surface opposite to the first surface, the first surface has a first soldering pad on the periphery of the insertion hole, and the second surface has a second soldering pad on the periphery of the insertion hole.

8. The PCB of claim 6, wherein an inner wall of the insertion hole has a first electric conducting layer.

9. The PCB of claim 8, wherein an inner wall of the heat gathering hole has a second electric conducting layer.

10. The PCB of claim 9, wherein the first electric conducting layer or the second electric conducting layer is a copper foil layer.

11. The PCB of claim 6, wherein a number of the heat gathering holes is proportional to the aperture size of the insertion hole.

12. The PCB of claim 11, wherein a ratio of the aperture size of the insertion hole to a number of the at least one heat gathering hole is ranged from 15% to 35%.

13. The PCB of claim 6, wherein the insertion hole or the heat gathering hole is an elliptical hole or a circular hole.

14. The PCB of claim 6, wherein an aperture size of the heat gathering hole is ranged from 0.6 mm to 0.8 mm.

15. The PCB of claim 6, wherein a distance between the heat gathering hole and the insertion hole is ranged from 0.4 mm to 0.6 mm.

16. A process for manufacturing a printed circuit board, comprising:
providing a base;
disposing at least one insertion hole on the base; and
disposing at least one heat gathering hole around the insertion hole.

17. The process of claim 16, wherein the base has a first surface and a second surface opposite to the first surface, the first surface has a first soldering pad on the periphery of the insertion hole, and the second surface has a second soldering pad on the periphery of the insertion hole.

18. The process of claim 17, further comprising:
forming a first electric conducting layer on an inner wall of the insertion hole.

19. The process of claim 18, further comprising:
forming a second electric conducting layer on an inner wall of the heat gathering hole.

20. The process of claim 19, further comprising:
sending the PCB inserted with the electronic component into a solder furnace having solder so as to enable the solder to adhere to the inner wall of the insertion hole, and enable the pin of the electronic component to be soldered to the second surface.
